(19) United States
(12) Patent Application Publication
(10) Pub. No.: US 2003/0112862 A1
(43) Pub. Date: Jun. 19, 2003

(54) Method and apparatus to generate ON-OFF keying signals suitable for communications

(75) Inventors: Jurianto Joe, Singapore (SG); Chwee Mei Wong, Singapore (SG)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: THE NATIONAL UNIVERSITY OF SINGAPORE

(21) Appl. No.: 10/095,972

(22) Filed: Mar. 11, 2002

Related U.S. Application Data
(60) Provisional application No. 60/340,130, filed on Dec. 13, 2001.

(51) Int. Cl. H03K 7/08

(52) U.S. Cl. 375/238; 375/239; 455/39

(57) ABSTRACT

A method and apparatus to generate an OOK-type of signal for transmitting digital data without having to use conventional mixer and oscillator circuitry as the carrier source is disclosed. The method utilizes a circuit that has a transfer characteristic comprising alternating unstable and stable operating regions, which produce respectively non-oscillatory and oscillatory output. The circuit is further characterized by having an operating point that can drive the circuit into stable or unstable operation based on the digital data. The resulting output signal is an OOK-type of signal suitable for transmission.

### CROSS-REFERENCES TO RELATED APPLICATIONS

This application claims the benefit of U.S. Provisional Application No. 60/340,130, filed Dec. 13, 2001, entitled “METHOD AND APPARATUS TO GENERATE AMPLITUDE SHIFT KEYING SIGNAL.”

This application is related to commonly owned U.S. Pat. No. 6,259,390. This application is further related to U.S. application Ser. No. 09/805,854, filed Mar. 13, 2001, entitled “Method and Apparatus to Recover Data From Pulses” which is hereby incorporated by reference for all purposes.

### STATEMENT AS TO RIGHTS TO INVENTIONS MADE UNDER FEDERALLY SPONSORED RESEARCH OR DEVELOPMENT

NOT APPLICABLE

### REFERENCE TO A “SEQUENCE LISTING,” A TABLE, OR A COMPUTER PROGRAM LISTING APPENDIX SUBMITTED ON A COMPACT DISK.

NOT APPLICABLE

### BACKGROUND OF THE INVENTION

This invention relates generally to signal modulation and more specifically to generation of signals using an ON-OFF keying modulation technique.

In a communication system, an analog or digital information can be modulated on a carrier signal before it is transmitted over a physical channel. OOK (on-off keying) is a common modulation method used in a digital communication systems. While it is generally accepted that it is not an ideal modulation method, it is a very simple method to implement and thus has application in appropriate situations.

FIG. 9 shows a conventional technique of producing an OOK modulated signal. A mixer 906, typically a nonlinear three-port device, is used as an OOK modulator. The mixer comprises three ports 901, 902 and 903. A data signal 905 is provided to input port 901. A carrier signal is generated by an oscillator 904 and is provided to input port 902 of the mixer. A resulting OOK modulated signal is produced at output port 903.

The current state of the art improves the cost performance of the OOK modulator 906. For example, U.S. Pat. No. 6,087,904 discloses an OOK modulator that can be implemented on a chip. The transformers, which are usually required in the mixer, are removed thus reducing device cost. A further OOK modulator improvement is disclosed in U.S. Pat. No. 6,292,067. In this patent, the OOK modulator only needs a positive-voltage power source which reduces implementation costs further. However, the method to generate OOK modulated waveform is essentially the same.

Although there has been significant progress in making the OOK modulator cheaper and smaller, the conventional method always requires a power consuming subsystem, such as oscillator 904 to provide the OOK modulator with the carrier. Furthermore, the oscillatory component can be an interference source in a transceiver because the power it generates is relatively high. For example, in a transceiver, the carrier signal generated by an oscillator used in the transmitter to up-convert data signal could interfere with the received signal that is much weaker and therefore reduce the sensitivity of the receiver.

There remains room for improvement of OOK modulation-based communication systems.

### BRIEF SUMMARY OF THE INVENTION

Transmission of digital data in accordance with embodiments of the invention include applying an input signal based on a digital data stream to a non-linear circuit configured to produce oscillatory signals and non-oscillatory signals based on the input signal. The non-linear circuit produces oscillatory signals when the input signal is at a first signal amplitude and produces a non-oscillatory signal when the input signal is at second signal amplitude. The resulting oscillatory and non-oscillatory signals are suitable for transmission.

In one embodiment of the invention, the input signal is the digital data stream itself. In another embodiment of the invention, the input signal is a pulse code modulated signal representative of the digital data stream.

### BRIEF DESCRIPTION OF THE DRAWINGS

The teachings of the present invention can be readily understood by considering the following detailed description in conjunction with the accompanying drawings:

FIG. 1 is a high level architectural diagram illustrating an OOK modulator according to the present invention;

FIG. 2 shows a non-linear circuit as used in an OOK modulator according to the present invention;

FIG. 3 shows alternating stable and unstable operating regions in a transfer function of the non-linear circuit shown in FIG. 2;

FIG. 4 shows an illustrative embodiment of a non-linear circuit according to the present invention;

FIG. 5 is a signal trace of signals produced in accordance with the present invention;

FIG. 6 shows a typical communication system component adapted in accordance with the present invention;

FIG. 7 shows another typical communication system component adapted in accordance with the present invention;

FIG. 8 is a block diagram of a radio frequency identification (RFID) technique adapted in accordance with the present invention; and

FIG. 9 shows a prior art signal generating system.

### DETAILED DESCRIPTION OF THE INVENTION

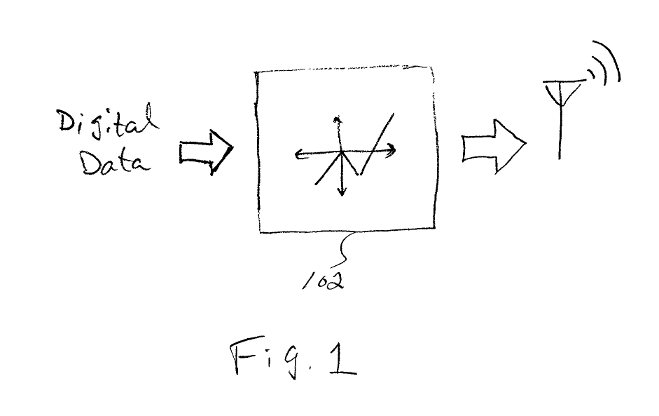

FIG. 1 is a generalized diagram illustrating an OOK modulator 102 according to the present invention. Digital data feeds into the modulator to produce an OOK-like signal representative of the digital data. An output of the modulator is a modulated signal suitable for transmission, and in an illustrated embodiment serves as the transmission signal itself.

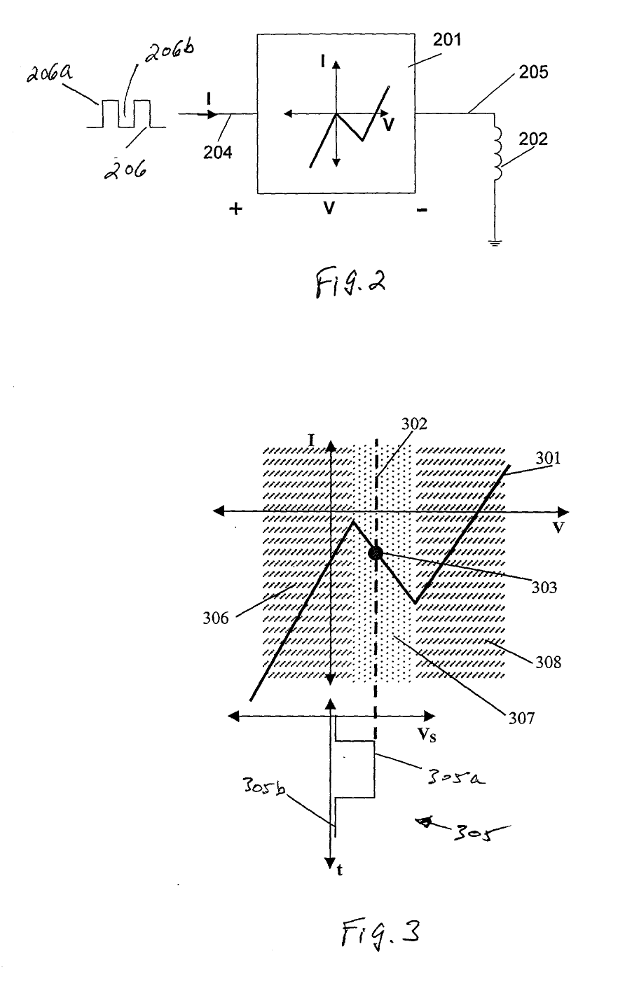

FIG. 2 is a high level function diagram of a circuit 201 comprising the OOK modulator 102 in accordance with an illustrative embodiment of the invention. The embodiment shows a circuit element 201 which has an N-shaped I-V transfer characteristic. A data signal 206 can be provided to an input port 204 of the circuit. An inductor 202 is coupled at an output 205 of the circuit.

As will be explained shortly, the circuit 201 produces a modulated signal representative of the data signal 206, which can be obtained from output port 205. If needed, a capacitor (not shown) can be connected across the inductor 202 to remove sharp edges or other high frequency components of the modulated signal. Similarly, a filter (not shown) can be connected to port 205 to remove the high frequency components of the waveforms generated. The data signal 206 includes two information regions 206a, 206b encoded in the amplitudes of the data signal.

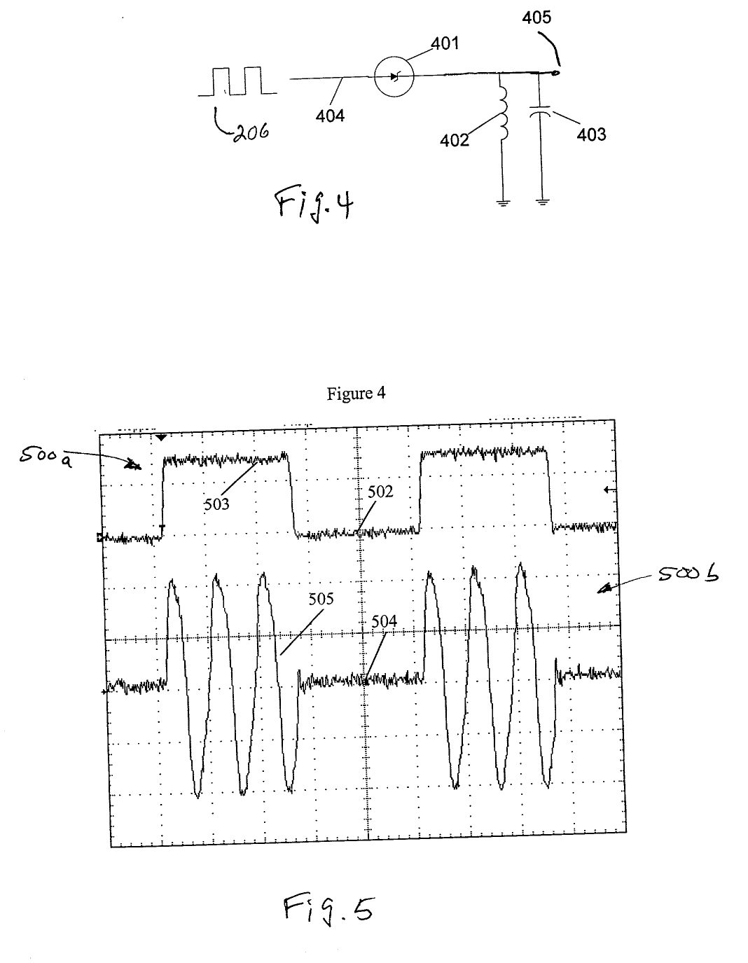

FIG. 4 shows an example of an implementation of the circuit 201. In this particular example, a tunnel diode 401 (e.g., part number is MP1605) serves as the circuit element 201. The value of the inductor 402 is about 10 μH. As noted above, a capacitor 403 can be added across the inductor 402 to smooth out the waveform generated. The capacitor value for this example is about 10 pF. The data signal 206 is applied to data input port 404. An OOK-type of modulated signal suitable for transmission can be tapped out from signal output port 405.

FIG. 3 shows a transfer function 301, I=Ψ(V), of the circuit 201 as implemented in FIG. 4. For the purposes of the present invention, the “transfer function” (characteristic) of a circuit refers to the relationship between any two state variables of a circuit. Electronic circuits are typically characterized by their I-V curves, relating the two state variables of current and voltage. Such curves indicate how one state variable (e.g., current) changes as the other state variable (voltage) varies. As can be seen in FIG. 3, the transfer function for the circuit of FIG. 4 includes a portion which lies within a region 307, referred to herein as an “unstable” region. The unstable region is bounded on either side by regions 306 and 308, each of which is herein referred to as a “stable” region.

The circuit of FIG. 4 has an associated “operating point” 303 which is a location on the transfer function 301. The nature of the output 405 of the circuit depends on the location of its operating point. If the operating point is positioned along the portion of the transfer function that lies within region 307, the output of the circuit will exhibit an oscillatory behavior. It is for this reason that the region 307 is referred to as an unstable operating region. If the operating point is positioned along the portions of the transfer function that lie within either of regions 306 and 308, the output of the circuit will exhibit a generally time-varying but otherwise non-oscillatory behavior. It is for this reason that regions 306 and 308 are referred to as stable operating regions.

The operating point 303 of the circuit is a function of the signal supplied to the input 404 of the circuit. FIG. 3 furthers shows such a control signal 305, having a first region 305a and a second region 305b. A line 302 is drawn to illustrate the relation of the amplitude of the control signal 305 Vₛ to the transfer function 301. The intersection of line 302 and transfer function 301 sets the operating point 303 of the circuit 201. Thus, as the control signal amplitude varies between amplitudes 305a and 305b, it can be seen that the operating point of the circuit of FIG. 4 moves between its stable and unstable operating regions, with corresponding changes in the behavior of the circuit output 405. Additional discussion of this and other circuits is provided in U.S. Pat. No. 6,259,390.

Thus, if the control signal 305 is replaced with the data signal 206, the operating point 303 of the circuit 201 will vary according to amplitude of the first information region 206a and the second information region 206b. An OOK-type of modulated signal then can be produced when the circuit is driven into the stable and unstable operating regions to produce non-oscillatory output and oscillatory output according to the data signal 206. The output of the circuit is an OOK signal if the pulse duty cycle of the data signal is 50%.

FIG. 5 are signal traces of an input data signal 500a and an output OOK modulated signal 500b. The input signal contains information region 502 (e.g., binary 0) and information region 503 (e.g., binary 1). Information region 502 places the operating point of the circuit 401 in the stable region (306 or 308, FIG. 3), while information region 503 places the operating point of the circuit 401 in the unstable region 307. When the operating point is in the stable region, a silent period 504 is observed at the output 500b. When the operating point is the unstable region, oscillations 505 are observed at the output. If the capacitor 403 is not present, the oscillation frequency is primarily determined by the value of inductor 402. However, if the capacitor 403 is present, the oscillation frequency is related by the expression f_{osc}=(2π)⁻¹(LC)^{-1/2}. L and C correspond to values of inductor 402 and capacitor 403 respectively. Thus, the oscillation frequency can be tuned as needed to be suitable for use as a transmitted signal.

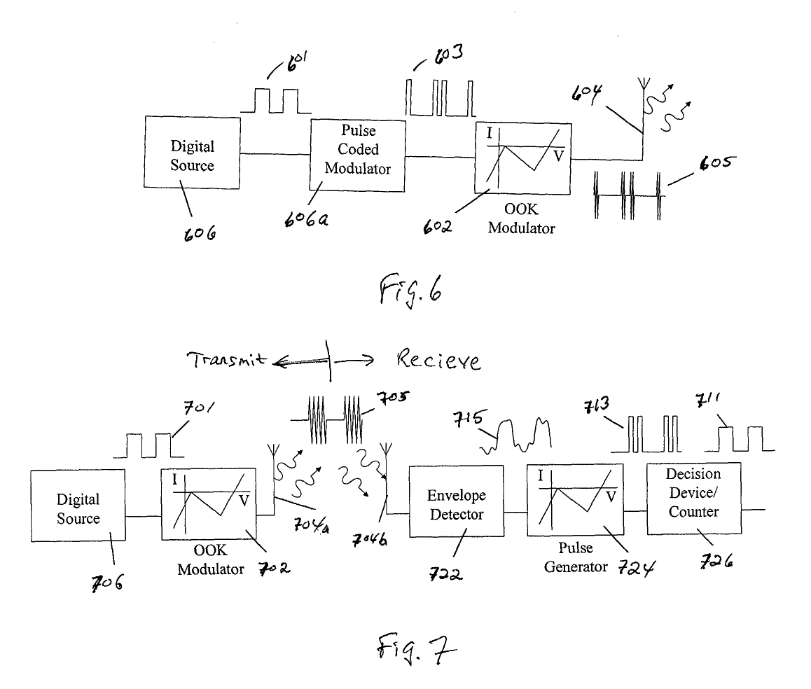

FIG. 6 is a high level block diagram of an ultra wideband (UWB) transmitter system adapted in accordance with the modulation technique of the present invention. A digital source 606 provides a serial digital data stream 601 that constitutes digital information to be transmitted. The digital data is encoded by a pulse coded modulator 606a. For example, the pulse code modulator might use a pulse position modulation (PPM) technique. Another pulse coding technique is pulse amplitude modulation (PAM). Still another commonly used pulse code modulation technique that can be used is pulse width modulation (PWM). In addition, the pulse coded modulator 606a may have spread spectrum capability such as Direct Sequence Spread Spectrum (DSSS).

The system 600 includes an OOK modulator 602 according to various embodiments of the present invention. The pulse encoded output 603 of the pulse coded modulator 606a is delivered to the OOK modulator 602. Typically, the pulse encoded output 603 will contain first and second information regions. The OOK modulator 602 produces an OOK-type of signal 605 in response to receiving the pulse encoded signal having portions which correspond to the first and second information regions of the pulse encoded output. The OOK-type of signal can then be transmitted to the air channel through an antenna 604 using conventional and known transmission techniques. As can be appreciated from the discussion above, the OOK-type of signal can generated without the use of a combined free running oscillator subsystem and mixer subsystem.

The transmitter embodiment illustrated in FIG. 6 can be used in conjunction with a UWB receiver such as disclosed in commonly owned, co-pending U.S. application Ser. No. 09/847,777 or as disclosed in U.S. application Ser. No. 09/970,385 to form a transceiver pair. To be compatible with the UWB transmitter shown in FIG. 6, an envelope detector should be used as the wave-shaper circuit shown in FIG. 1 of U.S. application Ser. No. 09/847,777.

FIG. 7 shows a block diagram of an amplitude shift keying (ASK) transceiver adapted in accordance with the present invention. At the transmitter side, a digital source 706 produces the digital serial data 701 which constitutes the digital information to be transmitted. The digital serial data is fed to an input to the OOK modulator 702. As in FIG. 6, a modulated signal 705 is produced at the output of the OOK modulator. The modulated signal is transmitted through the antenna 704a to the air channel to the receiver side. Optionally, an amplifier (not shown) may be inserted in between the OOK modulator 702 and the antenna 704a to amplify the modulated signal before transmission.

At the receiver side, the modulated signal 705 from the air, combined with noise and other interference signals, are received through the antenna 704b. The received signal may be amplified through an optional amplifier not shown) before it is inputted into an envelope detector 722. The envelope detector 722 will remove the carrier from the modulated signal 705 to produce an analog waveform 715. The analog signal, because of the noise and other interference effects of the transmission medium, resembles the original digital serial data 701, but with distortions.

The waveform 715 is then fed to a pulse generator 724 that has N-Shape I-V transfer characteristics. For example, such a circuit is described in U.S. Pat. No. 6,259,390. The output of the pulse generator 724 is a signal comprising groups of spikes 713 that are correlated with the analog waveform 715. These groups of spikes can be decoded by a counter or other decision device 726 to regenerate the digital information 711. Digital information 711 is identical to the digital serial data 701 when perfect transmission is successful. Examples of the algorithm used in the decision device 726 are more fully disclosed in U.S. application Ser. No. 09/805,854.

Alternatively, the digital information 711 can be recovered by performing hard decision analysis on analog waveform 715; for example by using a comparator. While this approach obviates the pulse generator 724 and decision device 726, it might not be suitable for all applications for reasons such as system performance, system robustness, and so on.

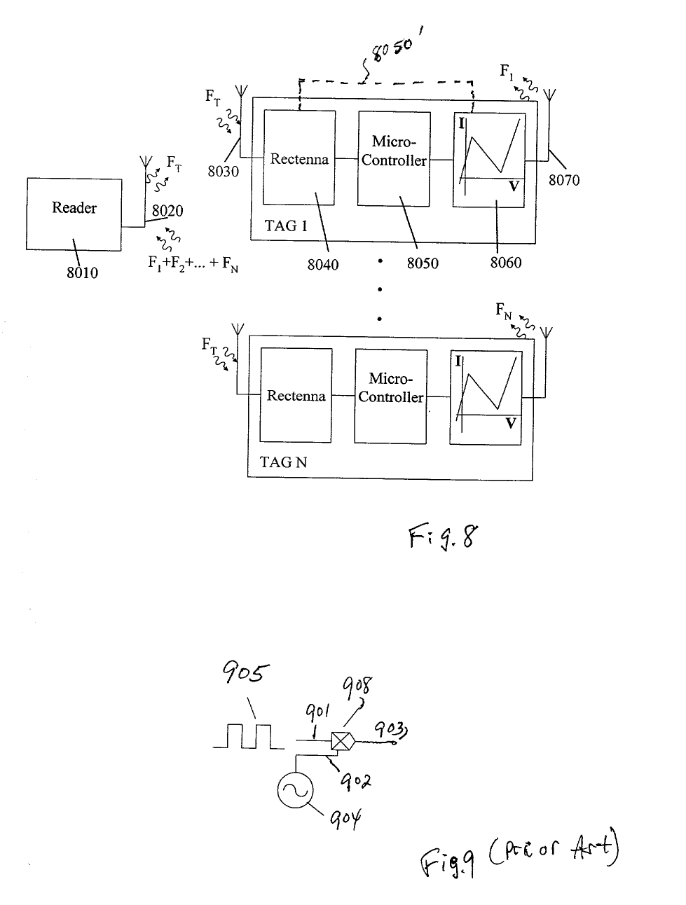

FIG. 8 shows a high level block diagram of another transmission system adapted in accordance with the present invention. A Radio Frequency Identification (RFID) system is shown. RFIDs employ the use of passive tags which are electronic devices tags that do not need a battery or like power source to operate. Instead, an RFID tag derives its power from a received signal transmitted to the tag.

In this system, a reader 8010 (also referred to as an interrogator) transmits an interrogator signal through antenna 8020 at frequency F_{T} to identify tags ID that are within its range. Each tag, Tag 1 to Tag N, will receive the interrogator signal and process it in the following manner. The tag will receive this signal through its antenna 8030. This signal will be converted to produce DC power by the rectenna (rectifying antenna) circuit 8040. The DC power can provide power to the microcontroller 8050 and to the OOK modulator. The microcontroller 8050 generates a digital bit stream containing first and second information regions. These first and second information regions are inputted into the OOK modulator 8060 to generate an OOK modulated signal. The OOK modulator 8060 for each tag may oscillate at a different frequency. This can be achieved, for example, by setting different values for inductor 402 (see FIG. 4) in each tag. In such a the case, the OOK modulated signal for each tag has different center frequency. Tag 1 will use center frequency F, (for example), and Tag N will use center frequency F_{N}. The advantage of using a different frequency for each tag is that there will not be information collision in the air.

The modulated signal transmitted from the OOK modulator 8060 can be transmitted through antenna 8070. In an embodiment of the invention, the antennae 8070 and 8030 can be combined into a single dual band antenna. The reader 8010 will be able to receive the signals transmitted from the tags via its antenna 8020. The antenna 8020 is appropriately configured to receive signals F₁ to F_{N}. The reader 8010 can post-process the signal F₁+. . . +F_{N} to identify which tag is present and what information is contained in each tag. Thus, for example, if F₃ is identified, then Tag 3 must be present and the information carried in the center frequency F₃ corresponds to the information contained in Tag 3.

A simpler version of an RFID system can be developed by removing the microcontroller 8050 in each tag. In this version, the rectenna 8040 is connected to the OOK modulator 8060. This alternate connection is illustrated in the figure by the dashed line 8050′. When the signal F_{T} is received, the rectenna 8040 converts the signal to produce DC and thus energize the OOK modulator 8060. The operating point 303 (FIG. 3) of the OOK modulator 8060 in this configuration is fixed to lie in the unstable region 307. The modulator will then simply oscillate at its oscillation frequency and transmit through its antenna 8070. The reader will be able to identify which tag is present by identifying the oscillation frequencies present in the air. This variation of RFID tags might suitable in an application where only simple identification is needed.

What is claimed is:

1. A method for generating a transmission signal suitable for transmitting a digital signal comprising:
receiving said data signal;
controlling a non-linear signal generating circuit with a control signal based on said digital signal, said non-linear signal generating circuit producing an oscillatory signal component when said control signal is at a first signal amplitude and a non-oscillatory signal component when said control signal is at a second signal amplitude, said transmission signal comprising one or more of said oscillatory and non-oscillatory signal components.

2. The method of claim 1 wherein said non-linear signal generating circuit has a transfer function comprising a stable operating region adjacent an unstable operating region, said control signal controlling said non-linear circuit to operate in a stable operating region or an unstable operating region depending on an amplitude of said control signal, wherein said oscillatory signal component is produced when said non-linear circuit is operating in an unstable operating region and said non-oscillatory signal component is produced when non-linear circuit is operating in a stable operating region.

3. The method of claim 1 wherein said control signal is a pulse code modulated signal based on said digital signal.

4. The method of claim 3 wherein said pulse code modulated signal is a pulse position modulated signal.

5. The method of claim 3 wherein said pulse code modulated signal is a pulse amplitude modulated signal.

6. The method of claim 3 wherein said pulse code modulated signal is a pulse position width signal.

7. A method for generating a transmission signal suitable for transmitting a digital signal comprising:
receiving said data signal;
producing a pulse code modulated signal based on said data signal; and
applying said pulse code modulated signal to a signal generating circuit to produce a transmittable signal;
said signal generating circuit characterized by a transfer function having an unstable operating region portion bounded one each side by a stable operating region portion,
said signal generating circuit having an operating point that lies on a location on said transfer function, said location being dependent on said pulse code modulated signal, wherein said signal generating circuit produces an oscillatory signal when said operating point is located in said unstable region and wherein said signal generating circuit produces a non-oscillatory signal when said operating point is located in one of said stable operating regions,
said operating point being located in said unstable operating region when said pulse code modulated signal is at a first amplitude, thereby producing an oscillatory signal component in said transmittable signal,
said operating point being located in one of said stable operating regions when said pulse code modulated signal is at a second amplitude, thereby producing a non-oscillatory signal component in said transmittable signal.

8. The method of claim 7 further including transmitting said transmittable signal.

9. The method of claim 7 wherein said pulse code modulated signal is a pulse position modulated signal.

10. The method of claim 7 wherein said pulse code modulated signal is a pulse amplitude modulated signal.

11. The method of claim 7 wherein said pulse code modulated signal is a pulse position width signal.

12. A method for transmitting a digital data stream comprising:
receiving the digital data stream as a data signal comprising signal portions having a first signal amplitude and signal portions have a second signal amplitude;
applying said digital signal to a signal generating circuit to produce a transmission signal; and
transmitting said transmission signal,
said signal generating circuit characterized by a transfer function having an unstable operating region portion bounded one each side by a stable operating region portion,
said signal generating circuit having an operating point that lies on a location on said transfer function, said location being determined based on said digital signal, wherein said signal generating circuit produces an oscillatory signal when said operating point is located in said unstable region and wherein said signal generating circuit produces a non-oscillatory signal when said operating point is located in one of said stable operating regions,
said operating point being located in said unstable operating region when said digital signal is at said first signal amplitude, thereby producing an oscillatory signal component in said transmittable signal,
said operating point being located in one of said stable operating regions when said digital signal is at said second signal amplitude, thereby producing a non-oscillatory signal component in said transmission signal.

13. The method of claim 12 as used in a radio frequency identification device (RFID), the method further comprising:
receiving an interrogator signal at a first RFID; and
producing DC power from said interrogator transmitted signal, wherein said DC power is applied to a controller, said controller producing said digital data stream, wherein said transmission signal is at a first frequency.

14. The method of claim 13 as used in a radio frequency identification device (RFID), the method further comprising:
receiving said interrogator signal at second RFID; and
producing DC power from said interrogator transmitted signal, wherein said DC power is applied to a controller, said controller producing said digital data stream, wherein said transmission signal is at a second frequency.

15. A transmission device for transmitting digital information comprising:
pulse code modulator having an input to receive a digital data stream and operable to generate a pulse code modulated signal representative of said digital data stream; and
a signal generating circuit coupled to receive said pulse code modulated signal, said signal generating circuit operable to generate a transmission signal in response to said pulse code modulated signal, said signal generating circuit producing an oscillatory signal when said pulse code modulated signal is at a first signal amplitude and producing a non-oscillatory signal when said pulse code modulated signal is at a second signal amplitude.

16. The transmission device of claim 15 wherein said pulse code modulated signal is a pulse position modulated signal.

17. The transmission device of claim 15 wherein said pulse code modulated signal is a pulse amplitude modulated signal.

18. The transmission device of claim 15 wherein said pulse code modulated signal is a pulse width modulated signal.

19. A transmission device for transmitting digital data comprising:
a signal generating circuit having an input for receiving a digital data signal, said digital data signal comprising signal portions of a first signal amplitude and signal portions of a second signal amplitude, said signal generating circuit producing a transmission signal having oscillatory signal portions and stead state signal portions; and
an antenna component coupled to receive said transmission signal and configured to radiate said transmission signal as a transmitted signal,
said signal generating circuit characterized by a transfer function having an unstable operating region portion bounded one each side by a stable operating region portion,
said signal generating circuit producing an oscillatory signal when said digital data signal is at said first signal amplitude, said signal generating circuit producing a non-oscillatory signal when said digital data signal is at said second signal amplitude.

20. The device of claim 19 wherein said signal generating circuit comprises a tunnel diode having a first terminal coupled to receive said digital data signal and a second terminal; and an inductive element having a series connection between said second terminal and a ground potential connection.

21. The device of claim 19 wherein said signal generating circuit comprises a tunnel diode having a first terminal coupled to receive said digital data signal and a second terminal; an inductive element having a series connection between said second terminal and a ground potential connection; and a capacitive element coupled between said second terminal and said ground potential connection.

22. The device of claim 19 as used in a radio frequency identification device (RFID) further comprising:
a rectenna module having an input for receiving an interrogation signal and having a DC level output; and
a controller module coupled to be powered by said DC level,
said controller module having an output for outputting said digital data stream.

23. A digital data transmission device comprising:
means for receiving a digital data stream and producing a digital signal representative of said digital data stream; and
circuit means for generating a transmission signal in response to said digital signal, said transmission signal producing an oscillatory signal when said digital signal is at a first signal amplitude and producing a non-oscillatory signal when said digital signal is at a second signal amplitude,
said circuit means having a transfer function characterized by having alternating stable and unstable operating regions, wherein oscillatory signals are produced when said circuit means is operating in an unstable operating region and non-oscillatory signals are produced when said circuit means is operating in a stable operating region,
said circuit means operating in a stable region when said digital signal is at said first signal amplitude,
said circuit means operating in an unstable regions when said digital signal is at said second signal amplitude.

24. The device of claim 23 wherein said means for receiving includes a connection that couples said digital data stream directly to said circuit means.

25. The device of claim 23 wherein said means for receiving includes means for producing a pulse encoded signal as said digital signal.

26. The device of claim 23 wherein said pulse encoded signal is a pulse position modulated signal.

27. The device of claim 23 wherein said pulse encoded signal is a pulse amplitude modulated signal.

26. The device of claim 23 wherein said pulse encoded signal is a pulse width modulated signal.
